(19) United States
(12) Patent Application Publication
(10) Pub. No.: US 2008/0003778 A1
(43) Pub. Date: Jan. 3, 2008

(54) Low-temperature welding with nano structures

(75) Inventors: Greg Ten Eyck, Albuquerque, NM (US); Toh-Ming Lu, Loudonville, NY (US); Tansel Karabacak, Little Rock, AR (US); Dexian Ye, Troy, NY (US); Pei-I Wang, Troy, NY (US)

Correspondence Address: FOLEY AND LARDNER LLP;SUITE 500, 3000 K STREET NW, WASHINGTON, DC, 20007, US

(73) Assignee: Rensselaer Polytechnic Institute

(21) Appl. No.: 11/808,761

(22) Filed: Jun. 12, 2007

Related U.S. Application Data
(60) Provisional application No. 60/812,963, filed on Jun. 13, 2006.

(51) Int. Cl. H01L 21/30

(52) U.S. Cl. 438/455

(57) ABSTRACT

A method of bonding two substrates and a corresponding bonded structure are described. The method includes forming a first nanostructure layer comprising nanostructures on a first substrate. A second substrate is contacted with the first nanostructure layer. The first nanostructure layer is heated at a heating temperature below a melting temperature of the first and second substrates. The first nanostructure layer is cooled after heating the nanostructure layer such that the first substrate is bonded to the second substrate.

### RELATED APPLICATIONS

This application claims priority from U.S. provisional application 60/812,963 filed on Jun. 13, 2006, the entire contents of which are incorporated by reference.

### FIELD OF THE INVENTION

The present invention relates to a method of low-temperature welding with nanostructures and bonded structures formed thereby.

### BACKGROUND

It has been realized that the melting behavior of nanometers-size particles can be quite different from that of the bulk. For example, it has been reported that the melting of nanostructures is initiated with an enhanced surface diffusion. When the particle size is reduced, the ratio of surface to volume increases along with the surface curvature. This makes the atoms at the outer surface more prone to detach from their positions and diffuse on the surface as adatoms. This process can lead to a change in the shape of the particle at relatively low temperatures compared to the bulk melting point of the elemental material. Surface diffusion is followed by a partial melting of the nanostructure mainly within a thin layer close to the surface, which is called “surface melting” or “premelting.” The premelting generally occurs at temperatures much lower than the bulk melting point but the detailed values depend on the parameters such as size and morphology of the nanostructure, existence of impurities, defects, strain, and also crystallographic orientation at the surface. Finally, similar to the premelting, the interior melting of a nanoparticle can take place at temperatures lower than the bulk melting point. During premelting and interior melting, a particle generally changes its shape, such as from a rod to a sphere, in order to minimize the surface to volume ratio and therefore minimizes its surface energy.

### SUMMARY OF INVENTION

Although studies of the melting temperature of nanostructures have been performed, the present inventors now apply such nanostructures for use in low temperature welding applications.

According to one embodiment of the invention, a method of bonding two substrates is provided. The method comprises: forming a first nanostructure layer comprising nanostructures on a first substrate; contacting a second substrate with the first nanostructure layer; heating the first nanostructure layer at a heating temperature below a melting temperature of the first and second substrates; and cooling the first nanostructure layer after heating the nanostructure layer such that the first substrate is bonded to the second substrate.

According to another embodiment of the invention, a method of bonding two substrates is provided. The method comprises: forming a first nanostructure layer comprising nanostructures on a first bond layer of a first substrate; contacting a second bond layer of a second substrate with the first nanostructure layer; heating the first nanostructure layer at a heating temperature below a melting temperature of the first and second bond layers; and cooling the first nanostructure layer after heating the nanostructure layer such that the first substrate is bonded to the second substrate.

### BRIEF DESCRIPTION OF THE DRAWINGS

FIGS. 1A and 1B are schematics illustrating a method of bonding and a bonded structure according to an embodiment of the invention.

FIGS. 2A and 2B are schematics illustrating a method of bonding and a bonded structure according to another embodiment of the invention.

FIGS. 3A and 3B are schematics illustrating a method of bonding and a bonded structure according to another embodiment of the invention.

FIGS. 4(a) through 4(n) are SEM image top views (left column) and cross-sectional views (side column) of copper nanorod arrays annealed at various temperatures.

FIG. 5 is a TEM image of an individual as-deposited copper rod.

FIGS. 6(a) and 6(b) are XRD spectra of Cu(111) and Cu(220) for Cu nanorod samples at various annealing temperatures.

FIGS. 7(a) and 7(b) are XRD spectra of Cu(111) and Cu(220) for a bulk Cu film at various annealing temperatures.

FIGS. 8A and 8B are schematics illustrating a method of bonding and a bonded structure according to another embodiment of the invention.

FIG. 9 is a graph illustrating the approximate melting temperature of Cu nanorods as a function of particle size and the melting temperature of bulk Cu.

### DESCRIPTION OF EMBODIMENTS OF THE INVENTION

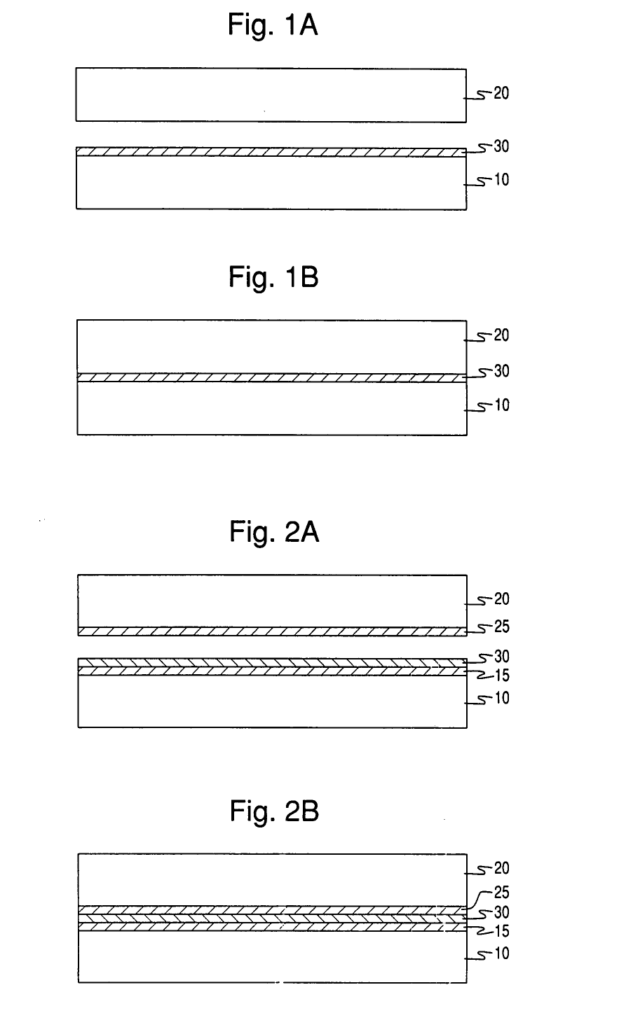

FIG. 1A illustrates a first substrate 10 and a second substrate 20 which are to be bonded together according to one embodiment of the invention. The first substrate 10 has a nanostructure layer 30 formed thereon. The first substrate 10 may be any substrate upon which the nanostructure layer 30 may be formed, such as, for example, a silicon or other semiconductor substrate with and insulator such as amorphous silicon nitride or silicon oxide formed thereon. The second substrate 20 may be any appropriate substrate. For example, the second substrate 20 may be identical to the first substrate. Alternatively, the second substrate 20 may be different from the first substrate 10.

The first nanostructure layer 30 may be formed using glancing angle deposition technique (GLAD), so as to deposit a copper nanorod array, for example. The invention is not limited to such nanostructures, and other materials may be formed as the nanostructure layer 30, and the nanostructures may be other than rods in shape. Moreover, other methods of deposition may be used to form the nanostructure layer, such as sputtering, thermal evaporation, and e-beam evaporation, for example. If the nanostructure layer 30 comprises nanorods, preferably the average diameter of the nanorods is less than about 100 nm.

After the nanostructure layer 30 is formed on the first substrate 10, the first substrate 10 with the nanostructure layer 30 formed thereon is brought into contact with the second substrate 20, with the nanostructure layer 30 contacting the second substrate 20 as shown in FIG. 1B. The nanostructure layer 30 is then heated to a heating temperature below a melting temperature of the first and second substrates and then cooled so that the first substrate 10 and the second substrate 20 are bonded together to form a bonded structure. Preferably, the heating temperature is less than one half of the melting temperature of the material of the nanostructures, if that material were in bulk form, where the heating temperature and melting temperature of the material in bulk form are given in degrees Kelvin. The heating and cooling may be performed in an annealing chamber, for example. In addition to heating the nanostructure layer 30, pressure may be applied to the first substrate 10 and second substrate 20, to press the substrates together to further lower the temperature at which the nanostructure layer 30 melts to thereby lower the temperature necessary to provide bonding between the first substrate 10 and the second substrate 20. Impurities may also be added to the nanostructure layer to further lower the temperature at which the nanostructure layer 30 melts.

In the case that a nanostructure layer is formed on both the first substrate 10 and the second substrate 20, the nanostructure layers may be brought into contact with each other. Preferably, a nanostructure layer is formed on both the first substrate 10 and the second substrate 20.

Preferably, the heating temperature is below the melting temperature of the material of the nanostructure layer 30, if that material were in bulk form. For example, if the nanostructure layer 30 comprises copper nanorods, the heating temperature would be below the melting temperature of bulk copper. The heating temperature may be above the premelting temperature of the nanostructures, for example, but below the melting or remelting temperature of the material of nanostructures in bulk form. At the premelting temperature, the surface of the nanostructure layer 30 begins to melt.

The nanostructure layer 30 may be formed of materials other than Cu, such as for example, W, Ru, Ni, and/or Au.

FIGS. 2A-2B illustrate a second embodiment where both the first substrate 10 and the second substrate 20 each include a bond layer. The first substrate 10 includes a first bond layer 15, while the second substrate 20 has a second bond layer 25. Either the first bond layer 15 or the second bond layer 25, or preferably both, may have a nanostructure layer formed thereon. For example, as shown in FIG. 2A, the first bond layer 15 has a first nanostructure layer 30 formed thereon. The first nanostructure layer 30 in this second embodiment may be formed in a fashion similar to that in the first embodiment, for example, such as by GLAD, sputtering, thermal evaporation, or e-beam evaporation. The nanostructure layer 30 may be formed of materials such as, for example, Cu, W, Ru, Ni, and/or Au.

After the nanostructure layer 30 is formed on the first bond layer 15, the first substrate 10 with the first bond layer 15 and nanostructure layer 30 formed thereon is brought into contact with the second bond layer 25 of the second substrate 20, where the nanostructure layer 30 contacts the second bond layer 25 as shown in FIG. 2B. The nanostructure layer 30 is then heated to a heating temperature below a melting temperature of the first and second bond layers and then cooled so that the first substrate 10 and the second substrate 20 are bonded together via the bond layers 15 and 25 to form a bonded structure. In a similar fashion to the first embodiment, the heating and cooling may be performed in an annealing chamber, for example, and optionally pressure may be applied to the first substrate 10 and second substrate 20, to press the substrates together.

In a similar fashion to the first embodiment, in the second embodiment preferably the heating temperature is below the melting temperature of the material of the nanostructure layer 30, if that material were in bulk form. For example, if the nanostructure layer 30 comprises copper nanorods, the heating temperature would be below the melting temperature of bulk copper. The heating temperature may be above the premelting temperature of the nanostructures, for example, but below the melting or remelting temperature of the material of nanostructures in bulk form.

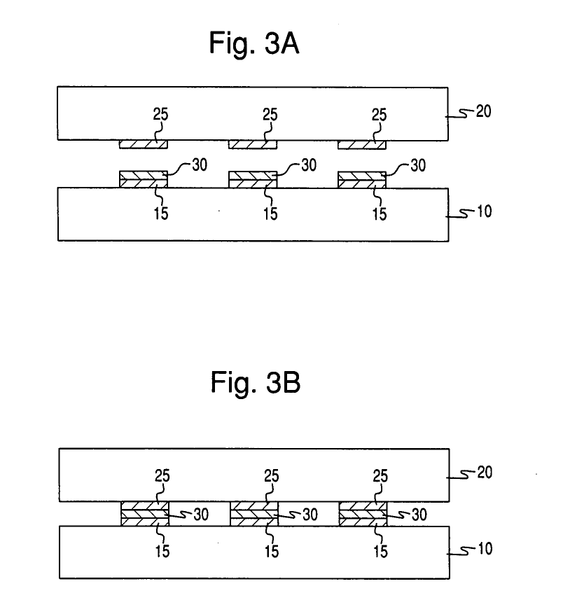

FIGS. 3A-3B illustrate a third embodiment where both the first substrate 10 and the second substrate 20 each include a bond layer, as in the second embodiment. In the third embodiment, however, the first bond layer 15, the second bond layer 25 and the nanostructure layer 30 are formed as patterned layers prior to the nanostructure layer 30 being contacted to the second bond layer 25. The patterned layers may be formed by depositing uniform layers of the first bond layer 15, the second bond layer 25 and the nanostructure layer 30, followed by patterning the uniform layers. For example, techniques such as photolithography, or laser patterning may be used. Alternatively, the patterned layers may be formed by selective deposition of the first bond layer 15, the second bond layer 25 and the nanostructure layer 30.

The bonding method may be used in a number of applications. For example, the bonding may be used for producing semiconductor devices. In this case, the substrates 10 and 20 for the first, second and third embodiments may be formed of a semiconductor material, such as germanium, silicon, or of a compound semiconductor, for example.

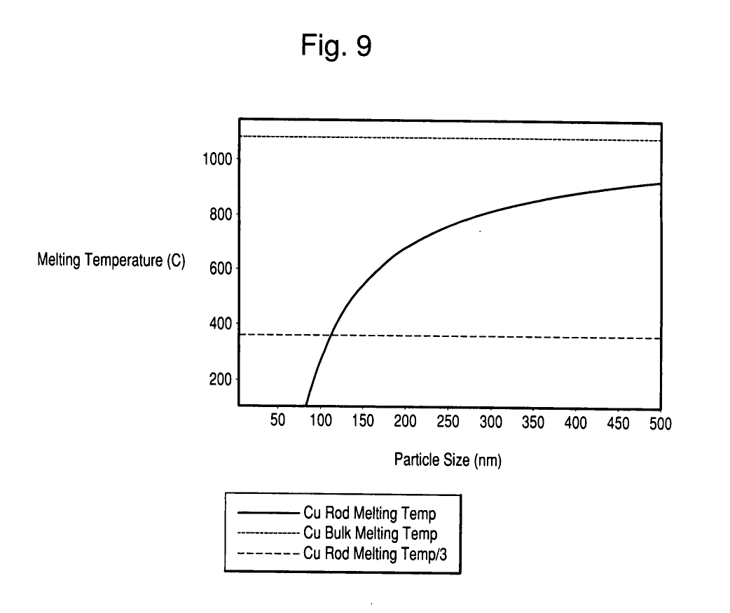

In general, the melting behavior of the nanostructure layer 30 will depend on the size of the particles of the nanostructures. While the invention is not limited to a particular mechanism for melting, the Gibbs-Thompson equation predicts a melting temperature depression, ΔTₘ, for small crystals of size d. Thus, the drop in melting temperature for a material formed as small crystals of size d as compared to the melting temperature of that material in bulk form is given by ΔTₘ. The Gibbs-Thompson equation is as follows: ΔTₘ=Tm_{bulk}−Tₘ(d)=(4·σₛₗ·Tₘ)/d·ΔH_{f}·ρₛ, where d is the crystal size, σₛₗ is the surface energy of the solid-liquid interface, Tm_{bulk} is the bulk melting temperature of the material, Tₘ(d) is the melting temperature of crystals of size d, ΔH_{f} is the bulk enthalpy of fusion (per g of material), and ρₛ is the density of the solid. FIG. 9 provides an approximation to illustrate the melting temperature of Cu nanorods as a function of particle size based on the above Gibbs-Thompson equation as compared to the melting temperature of bulk Cu. As can be seen from FIG. 9, the Gibbs-Thompson equation predicts an approximate melting temperature for the Cu nanorods of below 400° C. for a particle size of 100 nm. The Gibbs-Thompson equation as applied only provides an approximation of the melting temperature, and does not take into account the specific shape of the nanorods.

Deposition Method

As discussed above, the method of forming the nanostructure layer may include sputtering, thermal evaporation, e-beam evaporation or GLAD. One example of forming a nanostructure layer with Cu nanorods by GLAD is given below.

An oblique angle, dc magnetron sputtering system was used to deposit Cu nanorods. The depositions were performed on ˜300 nm thick amorphous silicon nitride films coated on p-Si(100) (resistivity 12-25 Ω-cm) substrates (˜3×4 cm² size) using a 99.95% pure Cu cathode (diameter ˜7.6 cm). The silicon nitride was deposited by a plasma enhanced chemical vapor deposition system and this layer was used to minimize Si impurity effect on the melting of copper nanorods at the interface between the Si substrate and the Cu. The distance between the substrate and cathode was ˜18 cm. During the growth, the substrate was tilted so that the angle between the surface normal of the substrate and the surface normal of the target was ˜85°. A base pressure of ˜4×10⁻⁷ Torr was used for the deposition. In all the sputter depositions the power was 200 Watts with an ultra pure Ar pressure of 2.0 mTorr. The deposition rates were measured to be ˜46 nm/min for normal incidence and ˜8 nm/min for oblique angle incidence as determined by a step-profilometer and also verified by scanning electron microscopy (SEM) cross-sectional images.

Premelting Temperatures

The melting of the Cu nanostructures was investigated by annealing the copper samples to determine the premelting temperatures of the Cu nanorods. The annealing of copper samples was performed in a mini-lamp annealing system. Due to the high thermal conductivity of the copper and the Si substrate, the heating rate used was expected to provide a uniform annealing of both the surface and the interior of Cu rods. The samples were kept at a desired annealing temperature for 30 minutes, then followed by a cooling step with a ramp-down rate of 17° C./min. Separate samples were annealed at various temperatures ranging from 300° C. to 800° C. with 50° C. increments.

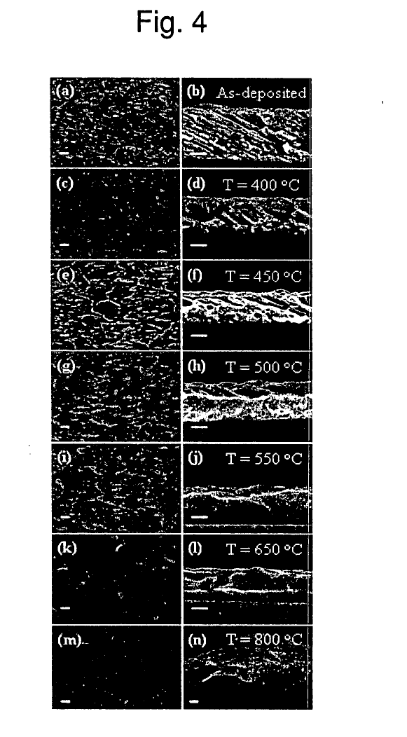

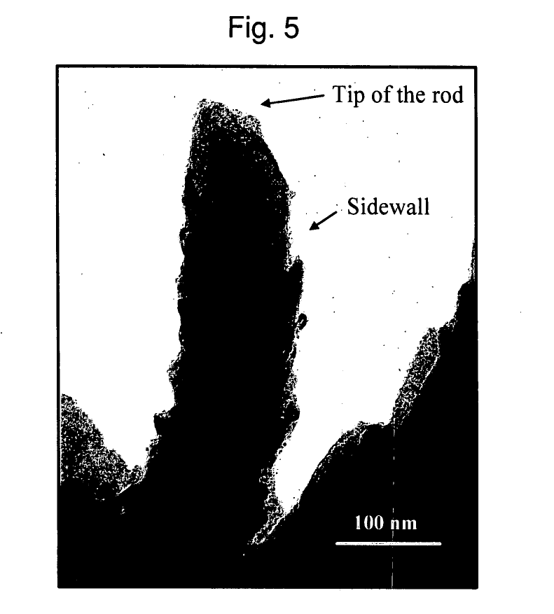

FIGS. 4(a)-4(n) show top and cross-sectional SEM images of copper rods from as-deposited layers up to annealing temperatures of 800° C., respectively. FIGS. 4(a) and 4(b) show top and cross-sectional SEM images of as-deposited copper rods, respectively. As can be seen the rods are tilted towards the incident oblique angle flux. The tilt angle is ˜64.5±0.6 degrees as measured from the surface normal. The as-deposited nanorods are ˜2300 nm in length, ˜100 nm in diameter, and are separated from each other with gaps varying between ˜10 and 30 nm. The thickness of the rods layer is ˜1000 nm. FIG. 5 is a TEM image of an individual nanorod of the nanorods. The rods have finer features with sizes ranging from about 1-10 nm, branching out from their sidewalls.

Below a 400° C. annealing temperature, no significant change in the nanorods was observed from SEM images. However, starting at T=400° C., premelting behavior occurs, and the rods start to go through a morphological change where they appear to fuse to each other as can be seen in FIGS. 4(c) and 4(d). This change is even clearer at higher annealing temperatures up to ˜550° C. (FIGS. 4(e)-4(j)). The nanorod arrays coalesce and result in a densification of the structure. The densification is also associated with the change in the rod tilt angle of the rods.

As annealing temperatures go above 550° C., more drastic changes occur. The nanorods start to disappear and form a uniform thin film as a result of coalescence. For example, as shown in FIGS. 4(k) and 4(l) for T=650° C., the structure become a continuous film with a rough surface. It becomes even more dense at higher temperatures of 800° C. (FIGS. 4(m) and 4(n)). The surfaces of these high temperature films show facetted terrace structures (e.g. FIG. 4(m)), which is an indication of re-crystallization. For the samples annealed at temperatures close to 800° C., the film has been observed to partially delaminate from the substrate in the form of a film. FIG. 4(n) also shows the delaminated sections of the sample annealed at 800° C.

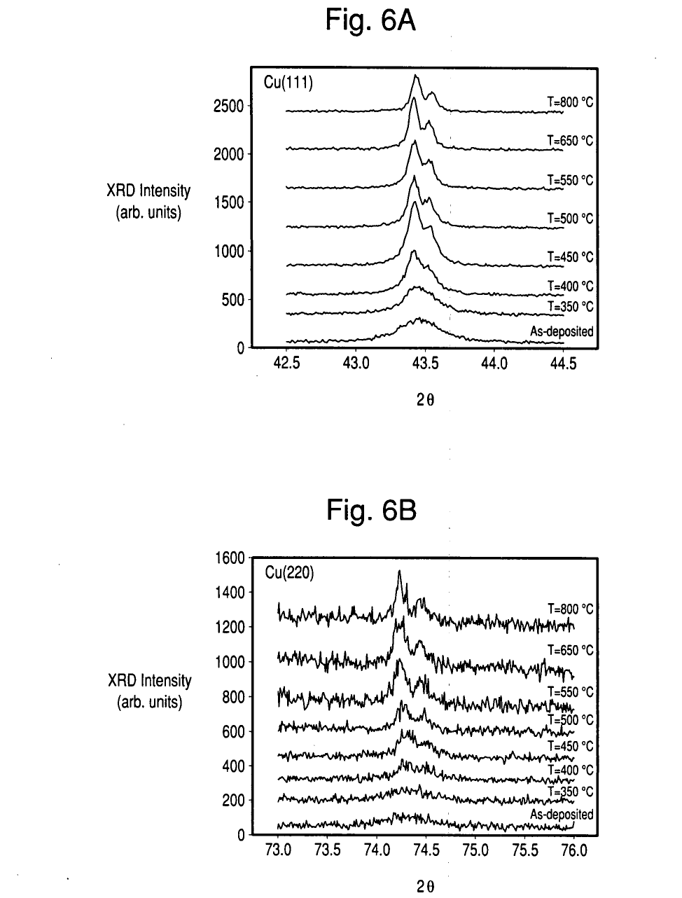

Further insight into the structural changes of the annealed Cu nanorod arrays can be obtained by x-ray diffraction (XRD) analysis. The re-crystallization of the melting are reflected in the intensity changes of the texture peaks in XRD. FIGS. 6(a) and 6(b) are plots of the Cu(111) and Cu(220) peaks as a function of annealing temperature, respectively. Table I summarizes the peak position values obtained from the XRD spectra.

TABLE I

| | | | Reduction |
|---|---|---|---|
| | | | in the |
| | | | lattice |
| | | | constant |
| | XRD Cu(111) | XRD Cu(220) | (compare |
| | 2θ peak | 2θ peak | to |
| Sample | position | position | 3.615 Å) |
| As deposited Cu nanorods | 43.46 ± 0.01° | 74.29 ± 0.02° | 0.25% |
| Cu nanorods after annealing | 43.42 ± 0.01° | 74.23 ± 0.01° | 0.22% |
| (T >400° C.) | | | |
| As deposited Cu film | 43.35 ± 0.01° | N/A | 0.08% |
| Cu film after annealing | 43.34 ± 0.01° | N/A | 0.06% |
| (T = 450° C.) | | | |

The as-deposited Cu nanorods have a weak Cu(111) texture normal to the surface located at 2θ˜43.46±0.01°, while the (220) peak located at ˜74.29±0.02° is almost absent. This is due to the tilted texture from the substrate normal as a result of shadowing during oblique angle deposition. These peak positions are slightly larger than their equilibrium values of 43.30° and 74.13° for the Cu(111) peak and the Cu(220) peak, respectively. This corresponds to a lattice constant ˜3.606 Å that is ˜0.25% smaller than the equilibrium value of 3.615 Å. This diffusion may be due to a tensile stress in the nanorods layer that reduces the lattice constant and pushes the XRD 0001s to larger 2θ positions.

No significant change in the XRD spectra was observed for annealing temperatures below 400° C. When the annealing temperature exceeded 400° C., the (111) peak shifted to a smaller 2θ (˜43.42±0.01°) closer to its equilibrium position, and became stronger in intensity and narrower in width. Also, the Cu(220) peak started to appear (2θ˜74.23±0.01°) especially at T>400° C. These spectra indicate re-crystallization and the formation of larger grains during annealing.

Based on the results of SEM and XRD measurements presented above, the copper nanorods appear to go through several temperature regimes before they completely melt. Below an annealing temperature of 400° C. neither the SEM nor XRD show any significant change in the structure of the rods. The melting process starts with the surface diffusion and premelting at ˜400° C., and results in the shape change and coalescence of the nanorods. At higher annealing temperatures >550° C., the rods starts to fuse to each other and form a denser, continuous, and (111) textured thin film. The surface of the rods melt in this temperature regime.

Bulk Cu Film Comparison

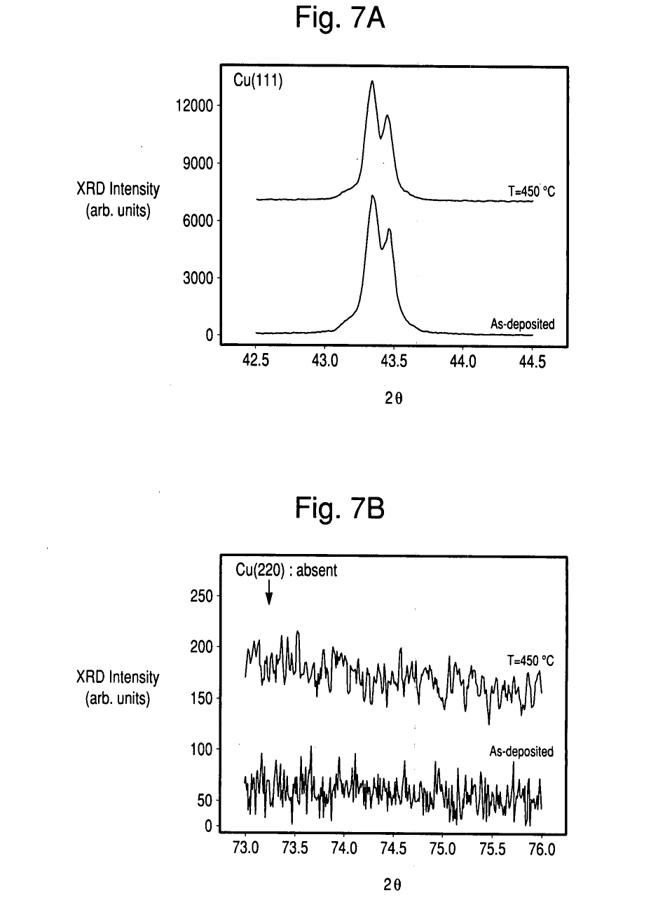

As a comparison to the nanorods samples, bulk Cu films of ˜700 nm thickness were deposited at normal incidence using the same sputtering system, and then annealed. The substrate was a silicon wafer with a native oxide layer. FIG. 7 shows the XRD results before and after annealing the Cu film sample at a temperature of 450° C., the temperature at which the nanorod samples started to show significant premelting characteristics. The as-deposited bulk Cu film shows a strong Cu (111) texture at 2θ˜43.35±0.01° and the (220) is absent down to the noise level. The Cu (111) peak position is closer to the equilibrium position of 43.30° compared to that of the nanorods (˜43.46°). This corresponds to a smaller tensile stress in the bulk Cu with a lattice constant value of 3.612 Å that is ˜0.08% smaller than the equilibrium value. The larger tensile stress in the Cu-nanorods compared to the bulk Cu-film may suggest that the stress in rods mainly originates from the voids formed during oblique angle growth. However, unlike nanorods, the XRD peak intensities of the bulk Cu film do not change as a result of annealing. After being annealed at 450° C., the intensity of the (111) peak does not increase and the (220) peak is still absent (the slight decrease in the (111) peak intensity is due to the smaller sample size used). These results suggest that the bulk copper film does not go through any significant surface diffusion or re-crystallization at annealing temperatures similar to those used on the nanorod samples.

### BONDING EXAMPLES

Bonding structures were prepared to show bonding between two Si substrates having Cu films formed thereon. Two substrates were prepared for each bond structure. Each substrate included a base substrate including a Si wafer followed by films of thermal oxide, Ta, and Cu. The Si wafers were 8 inches in diameter. A thermal oxide layer was formed on the Si wafer to a thickness of about 500 nm. The Ta layer was sputter deposited on the thermal oxide to a thickness of about 50 nm as an adhesion layer to subsequently deposited Cu. A Cu bond layer was then sputter deposited on the Ta layer thickness of about 500 nm.

### Bonding Example 1

For example 1, Cu was deposited by GLAD to form a Cu nanorod layer of about a 500 nm thickness on the Cu bond layer of each of the Cu bond layers of two base substrates prepared as above. The two substrates were then contacted together with the Cu nanorod layers contacting each other. A bonding pressure of 10 kN was applied to each of the substrates to press the substrates together, and a bonding temperature of 400 C was applied for a period of 60 minutes while the substrates were under pressure. An SEM image of a cross-section of the two wafer structure after annealing under pressure illustrated no clear interface between the nanorod layers of the two substrates indicating bond between the two substrates.

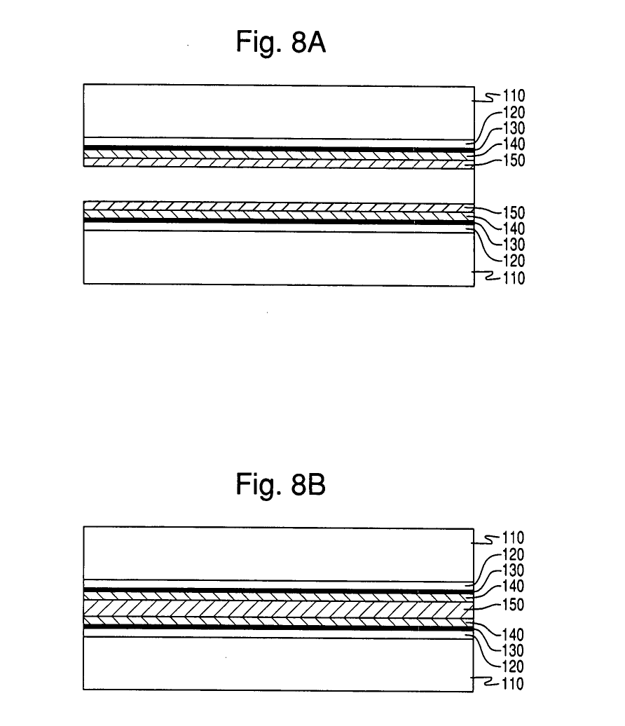

FIGS. 8A and 8B are schematics illustrating the bonding for bonding example 1. Each of the substrates prior to bonding as shown in FIG. 8A has a Si wafer 110, thermal oxide 120, Ta layer 130, Cu bond layer 140, and Cu nanorod layer 150. FIG. 8B illustrates the bonded structure after annealing at pressure.

### Bonding Example 2

For comparison, a bulk Cu film was deposited by e-beam to form a layer of about a 500 nm thickness on the Cu bond layer of each of the Cu bond layers of two base substrates prepared as above. The two substrates were then contacted together with the Cu e-beam Cu layers contacting each other. A bonding pressure of 10 kN was applied to each of the substrates to press the substrates together, and a bonding temperature of 400° C. was applied for a period of 60 minutes while the substrates were under pressure. In this case an SEM image of a cross-section of the two wafer structure after annealing under pressure illustrated a Cu—Cu interface between the e-beam layers of the two substrates indicating a lack of bond between the two substrates.

In general, the bonding between the substrates may occur even at premelting temperatures of the nanostructure layers. In such a case the bonding may possibly occur as a premelting sintering of the nanostructure layers with each other.

While the invention has been described with reference to several embodiments thereof, it will be understood by those skilled in the art that various changes may be made and equivalents may be substituted for elements thereof without departing from the scope of the invention. In addition, many modifications may be made to adapt a particular situation or material to the teachings of the invention without departing from the essential scope thereof. Therefore, it is intended that the invention not be limited to the particular embodiments disclosed as the best mode contemplated for carrying out this invention, but that the invention will include all embodiments falling within the scope of the appended claims.

1. A method of bonding two substrates comprising:
forming a first nanostructure layer comprising nanostructures on a first substrate;
contacting a second substrate with the first nanostructure layer;
heating the first nanostructure layer at a heating temperature below a melting temperature of the first and second substrates; and
cooling the first nanostructure layer after heating the nanostructure layer such that the first substrate is bonded to the second substrate.

2. The method of claim 1, further comprising:
forming a second nanostructure layer on the second substrate, wherein the contacting the second substrate with the first nanostructure layer comprises contacting the second nanostructure layer with the first nanostructure layer.

3. The method of claim 1, further comprising:
applying pressure to the first and second substrates during the heating of the first nanostructure layer.

4. The method of claim 1, wherein the first nanostructure layer comprises a plurality of nanorods having an average diameter of less than about 100 nm.

5. The method of claim 1, wherein the first nanostructure layer is formed using glancing angle deposition technique (GLAD).

6. The method of claim 1, wherein the first nanostructure layer comprises a material, and the heating temperature is below the melting temperature of the material in bulk form.

7. The method of claim 6, wherein the heating temperature is less than one half of the melting temperature of the material in bulk form where the heating temperature and melting temperature of the material in bulk form are given in degrees Kelvin.

8. The method of claim 6, wherein the first nanostructure comprise copper nanorods.

9. The method of claim 6, wherein the first nanostructure layer comprise a material selected from the group consisting of copper, tungsten, ruthenium, nickel, and gold.

10. A bonded structure comprising the first and second substrates of claim 1 formed by the method of claim 1.

11. A bonded structure comprising the first and second substrates formed by the method of claim 8.

12. The method of claim 1, wherein the first substrate and the second substrate each comprise a semiconductor material.

13. The method of claim 2, wherein the first nanostructure layer and second nanostructure layer each comprise a material, and the heating temperature is below the melting temperature of the material in bulk form.

14. The method of claim 13, wherein the heating temperature is less than one half of the melting temperature of the material in bulk form where the heating temperature and melting temperature of the material in bulk form are given in degrees Kelvin.

15. A method of bonding two substrates comprising:
forming a first nanostructure layer comprising nanostructures on a first bond layer of a first substrate;
contacting a second bond layer of a second substrate with the first nanostructure layer;
heating the first nanostructure layer at a heating temperature below a melting temperature of the first and second bond layers; and
cooling the first nanostructure layer after heating the nanostructure layer such that the first substrate is bonded to the second substrate.

16. The method of claim 15, further comprising:
forming a second nanostructure layer on the second substrate, wherein the contacting the second substrate with the first nanostructure layer comprises contacting the second nanostructure layer with the first nanostructure layer.

17. The method of claim 16, wherein the first nanostructure layer, second nanostructure layer, first bond layer and second bond layer are all of the same material.

18. The method of claim 15, further comprising:
applying pressure to the first and second substrates during the heating of the first nanostructure layer.

19. The method of claim 15, wherein the first nanostructure layer comprises a plurality of nanorods having an average diameter of less than about 100 nm.

20. The method of claim 15, wherein the first nanostructure layer is formed using glancing angle deposition technique (GLAD).

21. The method of claim 15, wherein the first nanostructure layer comprises a material, and the heating temperature is below the melting temperature of the material in bulk form.

22. The method of claim 21, wherein the heating temperature is less than one half of the melting temperature of the material in bulk form where the heating temperature and melting temperature of the material in bulk form are given in degrees Kelvin.

23. The method of claim 21, wherein the first nanostructure layer comprises copper nanorods.

24. The method of claim 23, wherein the first bond layer and second bond layer comprise a copper material.

25. The method of claim 21, wherein the first nanostructure comprise a material selected from the group consisting of copper, tungsten, ruthenium, nickel, and gold.

26. A bonded structure comprising the first and second substrates formed by the method of claim 15.

27. A bonded structure comprising the first and second substrates formed by the method of claim 23.

28. The method of claim 15, wherein the first bond layer and second bond layer comprise a same material.

29. The method of claim 28, wherein the first bond layer and second bond layer comprise a material selected from the group consisting of copper, tungsten, ruthenium, nickel, and gold.

30. The method of claim 15, wherein the first substrate and the second substrate each comprise a semiconductor material.
